(19) United States
(12) Patent Application Publication
(10) Pub. No.: US 2007/0046282 A1
(43) Pub. Date: Mar. 1, 2007

(54) Method and apparatus for semi-automatic generation of test grid environments in grid computing

(76) Inventors: Rhonda L. Childress, Austin, TX (US); Catherine Helen Crawford, Bedford, NH (US); David Bruce Kumhyr, Austin, TX (US); Paolo Franco Magnone, Palisades Park, NJ (US); Neil R. Pennell, Cedar Creek, TX (US)

Correspondence Address: IBM CORP (YA);C/O YEE & ASSOCIATES PC, P.O. BOX 802333, DALLAS, TX, 75380, US

(21) Appl. No.: 11/216,960

(22) Filed: Aug. 31, 2005

(51) Int. Cl. G01R 31/28

(52) U.S. Cl. 324/158.1

(57) ABSTRACT

Generating a description of a test grid environment for use in a grid computing environment. A database containing a number of test snapshots is generated. Each test snapshot reflects a previously used grid test environment, and each test snapshot includes a grid configuration used to implement a particular test scenario for a particular application. When a new, desired, test scenario is generated, a description of the new test scenario is entered as a query to the database. Based on the information in the database, a proposed test grid environment description is produced.

### BACKGROUND OF THE INVENTION

1. Field of the Invention

The present invention relates generally to an improved data processing system and in particular to a method, system, and computer usable code for processing data. Still more particularly, the present invention relates to a method, system, and computer usable code for generating test grid environments in grid computing.

2. Description of the Related Art

To save money related to the costs of maintaining computer resources, companies may outsource certain data processing operations. For example, a company maintains a certain amount of data processing resources to handle day-to-day data processing workloads, though from time to time the company may require additional data processing resources to handle overflow data processing workloads. Instead of paying the cost to maintain data processing resources sufficient to handle relatively infrequent workloads, the customer company pays a smaller cost to a provider to provide the data processing resources when needed. A customer that desires such outsourcing works with the provider to define and manage an arrangement that describes the work to be outsourced and the resources that need to be maintained. The arrangement between the customer and the provider may be referred to as a service level agreement.

Currently, grid computing is used to implement a service level agreement. Grid computing environments are data processing environments that enable software applications to integrate instruments, displays, and computational and information resources even when the software applications are managed by diverse organizations in widespread locations. Grid computing environments are different from other distributed network environments in that data processing systems in a grid computing environment share resources, even if the data processing systems are located in different geographic locations, are based on different architectures, or belong to different management domains. Thus, a computing grid represents a powerful pool of computing resources.

To implement a service level agreement, the local grid maintained by the customer is connected to one or more remote grids maintained by the provider. Resources from the remote grid are allocated to the local grid as defined in the service level agreement. However, the service level agreement may also provide that a customer may use a variable amount of resources on the remote grid. In this case, a customer may request remote resources to be allocated dynamically. However, a resource request in such an environment is often a complex description of requirements for hardware, software, networks, applications, and other systems which must be parsed before decisions may be made about available resource pools, pricing, and time to allocate such resources. Significant time, such as days to weeks, may be required to implement the requested changes.

In addition, the provider may not be able to predict which resources will be needed to handle a dynamic request for resources or which resources will physically function with other types of resources. Thus, it is desirable for a provider to build test grid environments in order to test the operation of a particular system configuration. Each test grid environment is designed to handle a particular type of customer request, though several test grid environments may have to be created and subsequent tests performed before a provider will know which system configuration should be finally implemented. Currently, a human operator performs the task of creating and running testing environments. However, due to the complexity of creating and running test grid environments, performing this task is time consuming, error prone, and difficult. Thus, it would be advantageous to have an improved method, apparatus, and computer usable code for generating test grid environments in grid computing.

### SUMMARY OF THE INVENTION

The present invention provides a method, system, and computer usable code for generating a description of a test environment for use in a grid computing environment. A database containing a number of test snapshots is generated. Each test snapshot reflects a previously used grid test environment, and each test snapshot includes a grid configuration used to implement a particular test scenario for a particular application. When a new test scenario is generated, a description of the new test scenario is entered as a query to the database. Based on the information in the database, a proposed test grid environment description is produced.

### BRIEF DESCRIPTION OF THE DRAWINGS

The novel features believed characteristic of the invention are set forth in the appended claims. The invention itself, however, as well as a preferred mode of use, further objectives and advantages thereof, will best be understood by reference to the following detailed description of an illustrative embodiment when read in conjunction with the accompanying drawings, wherein:

FIG. 1 depicts a pictorial representation of a network of data processing systems in which the present invention may be implemented;

FIG. 2 is a block diagram of a data processing system that may be implemented as a server in which the present invention may be implemented;

FIG. 3 is a block diagram illustrating a data processing system in which the present invention may be implemented;

FIG. 4 is a block diagram illustrating an architecture of a resource request and fulfillment system in accordance with an illustrative embodiment of the present invention;

FIG. 5 is a block diagram illustrating a hierarchical resource model in accordance with an illustrative embodiment of the present invention;

FIG. 6 is a block diagram of a test scenario in accordance with an illustrative embodiment of the present invention;

FIG. 7 is a block diagram of a test snapshot in accordance with an illustrative embodiment of the present invention;

FIG. 8 is a block diagram of a library of test snapshots in accordance with an illustrative embodiment of the present invention;

FIG. 9 is a block diagram illustrating uses of a library of test snapshots in accordance with an illustrative embodiment of the present invention;

FIG. 10 is an example of a dependency graph in accordance with an illustrative embodiment of the present invention;

FIG. 11 is a flowchart illustrating a method of generating and conducting one or more test grid environments in a grid computing environment in accordance with an illustrative embodiment of the present invention; and

FIG. 12 is a flowchart illustrating a method of generating a test scenario in accordance with an illustrative embodiment of the present invention.

### DETAILED DESCRIPTION OF THE PREFERRED EMBODIMENT

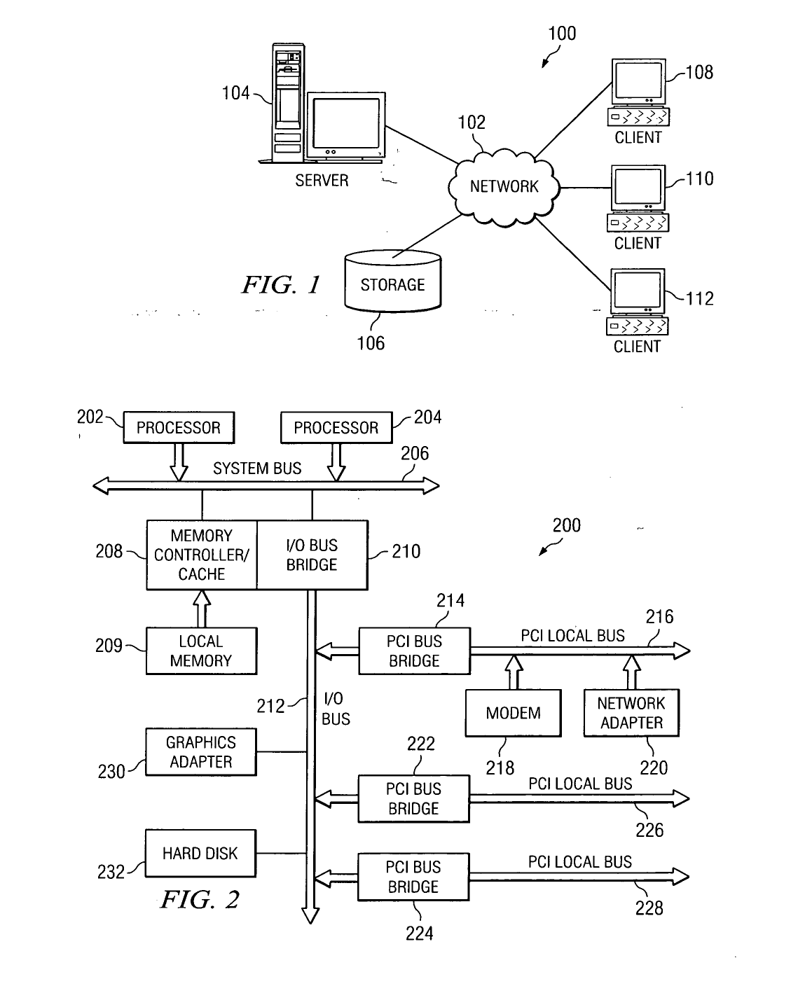

The present invention provides a method, system, and computer usable code for generating a description of a test environment for use in a grid computing environment. The data processing device may be a stand-alone computing device or may be a distributed data processing system in which multiple computing devices are utilized to perform various aspects of the present invention. Therefore, FIGS. 1-3 are provided as exemplary diagrams of data processing environments in which embodiments of the present invention may be implemented. It should be appreciated that FIGS. 1-3 are only exemplary and are not intended to assert or imply any limitation with regard to the environments in which aspects or embodiments of the present invention may be implemented. Many modifications to the depicted environments may be made without departing from the spirit and scope of the present invention.

With reference now to the figures, FIG. 1 depicts a pictorial representation of a network of data processing systems in which aspects of the present invention may be implemented. Network data processing system 100 is a network of computers in which embodiments of the present invention may be implemented. Network data processing system 100 contains a network 102, which is the medium used to provide communications links between various devices and computers connected together within network data processing system 100. Network 102 may include connections, such as wire, wireless communication links, or fiber optic cables.

In the depicted example, server 104 connects to network 102 along with storage unit 106. In addition, clients 108, 110, and 112 connect to network 102. These clients 108, 110, and 112 may be, for example, personal computers or network computers. In the depicted example, server 104 provides data, such as boot files, operating system images, and applications to clients 108-112. Clients 108, 110, and 112 are clients to server 104. Network data processing system 100 may include additional servers, clients, and other devices not shown.

In the depicted example, network data processing system 100 is the Internet with network 102 representing a worldwide collection of networks and gateways that use the Transmission Control Protocol/Internet Protocol (TCP/IP) suite of protocols to communicate with one another. At the heart of the Internet is a backbone of high-speed data communication lines between major nodes or host computers, consisting of thousands of commercial, government, educational and other computer systems that route data and messages. Of course, network data processing system 100 also may be implemented as a number of different types of networks, such as for example, an intranet, a local area network (LAN), or a wide area network (WAN). FIG. 1 is intended as an example, and not as an architectural limitation for different embodiments of the present invention.

Referring to FIG. 2, a block diagram of a data processing system that may be implemented as a server, such as server 104 in FIG. 1, is depicted in accordance with an illustrative embodiment of the present invention. Data processing system 200 may be a symmetric multiprocessor (SMP) system including a plurality of processors 202 and 204 that connect to system bus 206. Alternatively, a single processor system may be employed. Also connected to system bus 206 is memory controller/cache 208, which provides an interface to local memory 209. I/O bus bridge 210 connects to system bus 206 and provides an interface to I/O bus 212. Memory controller/cache 208 and I/O bus bridge 210 may be integrated as depicted.

Peripheral component interconnect (PCI) bus bridge 214 connects to I/O bus 212 provides an interface to PCI local bus 216. A number of modems may be connected to PCI local bus 216. Typical PCI bus implementations will support four PCI expansion slots or add-in connectors. Communications links to clients 108-112 in FIG. 1 may be provided through modem 218 and network adapter 220 connected to PCI local bus 216 through add-in connectors.

Additional PCI bus bridges 222 and 224 provide interfaces for additional PCI local buses 226 and 228, from which additional modems or network adapters may be supported. In this manner, data processing system 200 allows connections to multiple network computers. A memory-mapped graphics adapter 230 and hard disk 232 may also be connected to I/O bus 212 as depicted, either directly or indirectly.

Those of ordinary skill in the art will appreciate that the hardware depicted in FIG. 2 may vary. For example, other peripheral devices, such as optical disk drives and the like, also may be used in addition to or in place of the hardware depicted. The depicted example is not meant to imply architectural limitations with respect to the present invention.

The data processing system depicted in FIG. 2 may be, for example, an IBM eServer™ pSeries® computer system, running the Advanced Interactive Executive (AIX®) operating system or LINUX operating system (eServer, pSeries and AIX are trademarks of International Business Machines Corporation in the United States, other countries, or both while Linux is a trademark of Linus Torvalds in the United States, other countries, or both).

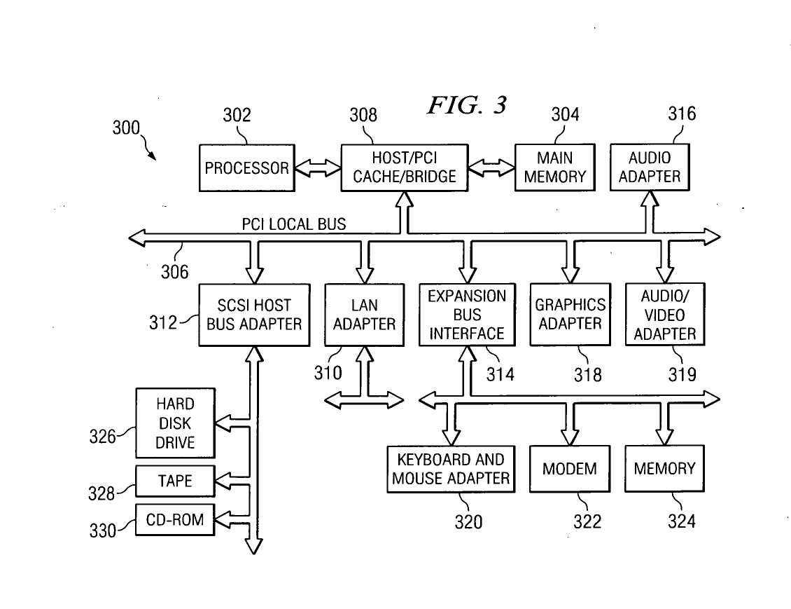

With reference now to FIG. 3, a block diagram of a data processing system is shown in which aspects of the present invention may be implemented. Data processing system 300 is an example of a computer, such as client 108 in FIG. 1, in which code or instructions implementing the processes for embodiments of the present invention may be located. In the depicted example, data processing system 300 employs a hub architecture including a north bridge and memory controller hub (MCH) 308 and a south bridge and input/output (I/O) controller hub (ICH) 310. Processor 302, main memory 304, and graphics processor 318 are connected to MCH 308. Graphics processor 318 may be connected to the MCH through an accelerated graphics port (AGP), for example.

In the depicted example, local area network (LAN) adapter 312, audio adapter 316, keyboard and mouse adapter 320, modem 322, read only memory (ROM) 324, hard disk drive (HDD) 326, CD-ROM drive 330, universal serial bus (USB) ports and other communications ports 332, and PCI/PCIe devices 334 connect to ICH 310. PCI/PCIe devices may include, for example, Ethernet adapters, add-in cards, PC cards for notebook computers, etc. PCI uses a card bus controller, while PCIe does not. ROM 324 may be, for example, a flash binary input/output system (BIOS). Hard disk drive 326 and CD-ROM drive 330 may use, for example, an integrated drive electronics (IDE) or serial advanced technology attachment (SATA) interface. A super I/O (SIO) device 336 may be connected to ICH 310.

An operating system runs on processor 302 and coordinates and provides control of various components within data processing system 300 in FIG. 3. The operating system may be a commercially available operating system such as Microsoft® Windows® XP (Microsoft and Windows are trademarks of Microsoft Corporation in the United States, other countries, or both). An object oriented programming system, such as the Java™ programming system, may run in conjunction with the operating system and provides calls to the operating system from Java programs or applications executing on data processing system 300 (Java is a trademark of Sun Microsystems, Inc. in the United States, other countries, or both).

Instructions for the operating system, the object-oriented programming system, and applications or programs are located on storage devices, such as hard disk drive 326, and may be loaded into main memory 304 for execution by processor 302. The processes for embodiments of the present invention are performed by processor 302 using computer implemented instructions, which may be located in a memory such as, for example, main memory 304, memory 324, or in one or more peripheral devices 326 and 330. These processes may be executed by any processing unit, which may contain one or more processors.

Those of ordinary skill in the art will appreciate that the hardware in FIGS. 1-3 may vary depending on the implementation. Other internal hardware or peripheral devices, such as flash memory, equivalent non-volatile memory, or optical disk drives and the like, may be used in addition to or in place of the hardware depicted in FIGS. 1-3. Also, the processes of the present invention may be applied to a multiprocessor data processing system.

As some illustrative examples, data processing system 300 may be a personal digital assistant (PDA), which is configured with flash memory to provide non-volatile memory for storing operating system files and/or user-generated data.

A bus system may be comprised of one or more buses, such as system bus 206, I/O bus 212 and PCI buses 216, 226 and 228 as shown in FIG. 2. Of course the buss system may be implemented using any type of communications fabric or architecture that provides for a transfer of data between different components or devices attached to the fabric or architecture. A communications unit may include one or more devices used to transmit and receive data, such as modem 218 or network adapter 220 of FIG. 2 or modem 322 or LAN 312 of FIG. 3. A memory may be, for example, local memory 209 or cache such as found in memory controller/cache 208 of FIG. 2 or main memory 304 of FIG. 3. A processing unit may include one or more processors or CPUs, such as processor 202 or processor 204 of FIG. 2 or processor 302 of FIG. 3. The depicted examples in FIGS. 1-3 and above-described examples are not meant to imply architectural limitations. For example, data processing system 300 also may be a tablet computer, laptop computer, or telephone device in addition to taking the form of a PDA.

The present invention provides a method, apparatus, and computer usable code for generating a description of a test environment for use in a grid computing environment. A database containing a number of test snapshots is generated. Each test snapshot reflects a previously used grid test environment, and each test snapshot includes a grid configuration used to implement a particular test scenario for a particular application. When a new test scenario is generated, a description of the new test scenario is entered as a query to the database. Based on the information in the database, a proposed test grid environment description is produced.

The proposed test grid environment description may be compared to a current grid environment description. If desired, the current grid environment may be changed to match the test grid environment description. However, several test grid environment descriptions may be generated and compared to the current grid environment description before actually changing the current grid environment. After changing the current grid environment to match the test grid environment, if necessary, a test scenario may be implemented on the new grid environment.

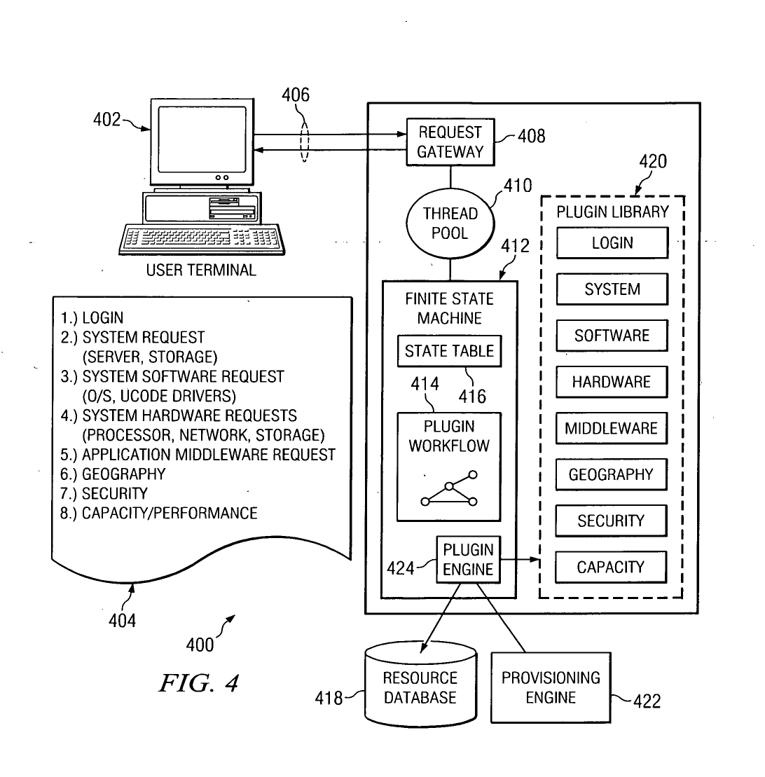

FIG. 4 is a block diagram illustrating resource request and fulfillment system architecture in accordance with an illustrative embodiment of the present invention. FIG. 4 shows system 400 for requesting resources in a grid computing environment in accordance with the present invention. A user request is input by a user using terminal 402, which may be part of or attached to a data processing system, such as server 104 or clients 108, 110, or 112 shown in FIG. 1. The request may be made over a network, such as network 102 shown in FIG. 1. The user request may be any of a plurality of different types of requests, such as those shown in block 404, and may include a login request, a system-level request for systems such as servers or storage, a system software request for software such as an operating system (O/S), microcode (μcode) or device/adapter driver(s), a system hardware request for hardware such as a processor, network or storage, an application middleware request, a geography request, a security request, and a capacity/performance request.

The user request is transmitted across path 406, which may be implemented as a network such as network 102 shown in FIG. 1, to request gateway 408, which may be implemented by a server such as server 104 shown in FIG. 1. At request gateway 408, a thread is created from thread pool 410. This thread creates finite state machine (FSM) 412 in request gateway 408 to handle subsequent signals and errors, such as request signals from the user and allowed or disallowed resource allocation attempts. Finite state machine 412 dynamically creates plug-in workflow 414 which manages, in conjunction with state table 416, different states of the request, including error conditions. Finite state machine 412 uses resource database 418 to determine if requested resources are available, and to temporarily commit resources until all signals in the request have been received. Plug-ins to translate requirements and coordinate with provisioning engine 422 are dynamically executed within runtime engine 424 in finite state machine 412.

These plug-ins are shown in section 420 and are a part of a plug-in library. These plug-ins may provide functions such as, for example, Login, System Request, System Software Request, System Hardware Request, Application Middleware Request, Geography, Security and Capacity/Performance, as shown in section 420. The System Request may be for a server or storage in this example, the System Software Request may be for a operating system, microcode, or drivers in this example, and the Systems Hardware Request may be for a processor, network, or storage in this example. An error or unavailable signal may be generated at any point based upon the state of the user request.

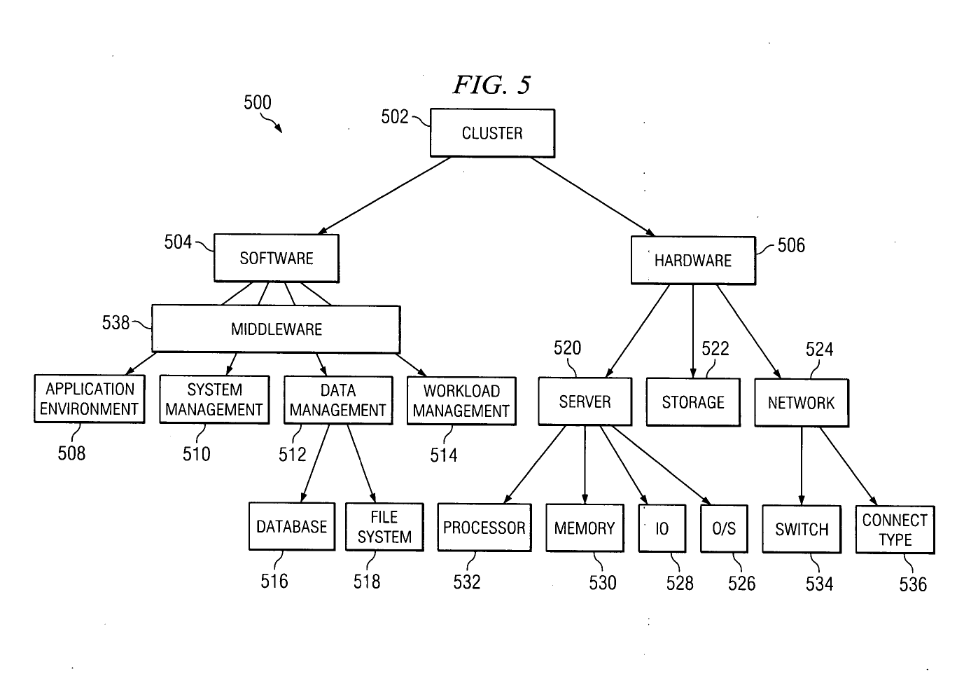

FIG. 5 is a block diagram 500 illustrating a hierarchical resource model in accordance with an illustrative embodiment of the present invention. A particular grid environment 502 is a system built using software 504 and hardware 506. Software 504 is built using application environment 508, system management 510, data management 512, and workload management 514. Data management 512 is built using one or more databases 516 and one or more file systems 518. Hardware 506 is built using servers, disks, and a network, as shown by server(s) 520, storage 522, and network 524. If a multitude of heterogeneous storage devices 522 are provided, such as disk storage devices and tape storage devices, the storage could be further modeled at a lower level to include both disk and tape storage devices.

Similarly, server 520 may be described using operating system 526, basic input/output 528, on board memory 530, and processor 532. A network may be described by switch 534 and the type of connectivity 536. In each of these instances, a hierarchy of atomistic resources, such as processor 532, storage 522, database 516, and system management 510, and compound resources, such as software 504 and hardware 506, are used to define the grid environment. A plurality of such grid environments may be further organized into a larger grid environment.

The illustrative grid environment shown in FIG. 5 may be varied from that shown. For example, more or fewer software or hardware dependencies may be added, such as printers, routers, communication systems, databases, applications, and other data processing systems and software systems.

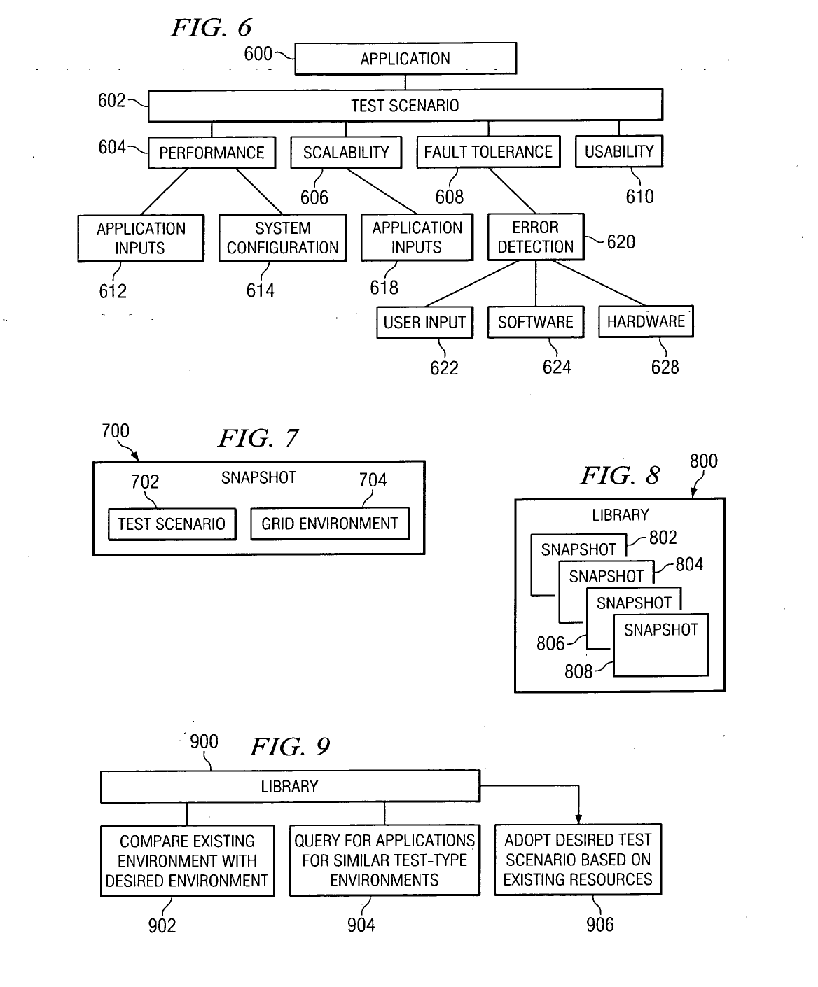

FIG. 6 is a block diagram of a test scenario in accordance with an illustrative embodiment of the present invention. Each particular test scenario 602 is associated with a particular application 600. Application 600 is executed in a grid environment, such the grid configuration shown in FIG. 5. However, application 600 may have a large number of application configurations. Each application configuration represents a test scenario, such as test scenario 602, because each application configuration may require a different grid configuration and each application configuration should be tested before being implemented.

In the illustrative example shown in FIG. 6, test scenario 602 includes four major factors, performance 604, scalability 606, fault tolerance 608, and usability 610. Performance 604 represents how a particular application configuration will perform on a particular grid environment. Scalability 606 represents how well an application configuration can adapt to a change in the scale that the application is implemented for a particular grid environment. Fault tolerance 608 represents how well a particular application configuration tolerates faults on a particular grid environment. Usability 610 represents how usable a particular application configuration is when installed on a particular grid environment.

Each of the major factors described above may have sub factors. For example, performance 604 includes application inputs 612 and system configuration 614. Application inputs 612 describe how application inputs affect the performance of the application in the particular configuration and on the particular grid environment. Similarly, system configuration 614 may affect application performance. In addition, scalability 606 may also be affected by application inputs 618, which may be different from or similar to application inputs 612. In addition, fault tolerance 608 may depend on error injections 620, which may in turn depend on errors from user inputs 622, bugs in software 624, and problems in hardware 628.

The illustrative application test scenario shown in FIG. 6 may be varied. For example, a particular test scenario may include more or fewer factors and sub-factors, such as speed, data presentation, and others.

FIG. 7 is a block diagram of test snapshot 700 in accordance with an illustrative embodiment of the present invention. In this example, test snapshot 700 is a database that includes information related to a particular test scenario 702 and associated particular grid environment 704. Test scenario 702 may be test scenario 600 shown in FIG. 6 and grid environment 704 may be grid environment 500 shown in FIG. 5. Accordingly, test snapshot 700 includes a description of test scenario 702 and a description of grid environment 704 upon which test scenario 702 has already been tested.

The database associated with test snapshot 700 may include basic information such as which particular application test scenario is associated with which particular grid environment. In this case, it may be assumed that a particular application test scenario will function adequately in the corresponding grid environment. However, the database associated with test snapshot 700 may also include additional information. For example, the database associated with test snapshot 700 may include information regarding how well a particular application test scenario operates in an associated grid environment, manually entered notes, or other information relevant to the application test scenario and the corresponding grid environment. The database may also include constructs that will be useful for comparison, such as the actual test cases and constants surrounding the test case. Those constructs may be items such as, successful execution of the test case, outcome of the test case, errors associated with the test case, time required to execute test case, resources available to the test case, or need of assistance for the test case to execute successfully.

FIG. 8 is a block diagram of a library of test snapshots in accordance with an illustrative embodiment of the present invention. Library 800 of test snapshots includes a number of test snapshots, such as test snapshot 802, test snapshot 804, test snapshot 806, and test snapshot 808. Each snapshot is similar to snapshot 700 in FIG. 7. Library 800 of test snapshots may be used as part of a larger database. Library 800 may also be associated with a search engine adapted to search information contained in library 800. Thus, library 800 may be used to semi-automatically generate test grid environments in grid computing, as described further below.

FIG. 9 is a block diagram illustrating uses of a library of test snapshots in accordance with an illustrative embodiment of the present invention. Library 900 is similar to library 800 shown in FIG. 8. Hence, library 900 includes a plurality of test snapshots, wherein each test snapshot includes a particular application test scenario associated with a particular grid environment. Similarly, library 900 may be used to semi-automatically generate test grid environments in grid computing. As an aspect of the present invention library 900 may contain test templates, test environment templates, known use case scenarios, and already exercised components. To be effective, library 900 may be searched based on the type of test, type of application and the type of environment to find the appropriate environment for the test.

Without library 900, if a direct comparison against all known test cases were attempted, the search would become very expensive. The idea is to gather a vast array of test templates, test environment templates, known use case scenarios, and already exercised components for utilization as compatible test grid environments. For example, as shown in block 902, library 900 may be used to compare an existing grid environment with a desired grid environment. The existing grid environment and the desire grid environment are each defined using workflow language.

Workflow language describes the ontology and taxonomy of test grid environments and testing scenarios. Specifically, ontology and taxonomy specifies the test environment components and dependencies in a hierarchical fashion. Current art specifies the hierarchy to build a cluster in terms of components and component based dependencies. For a test environment, the test cases themselves may be predicated on certain tests executing before others are performed. The union of the components and the dependencies is a novel concept for generating dynamic test grid environments. For example, a specific requirement may be a language for describing how a cluster may be constructed (servers, network, I/O, OS) as well as what tests may be run on that cluster simultaneously or independently, e.g. file system performance and gather/scatter computing operations. So each cluster may have a list of components and component dependencies, and relevant tests and test dependencies.

A data processing system may then compare the descriptions of each grid environment and produce a dependency graph to generate missing components in the grid environment, additional test scenarios to be run, and other useful information. This function is useful in any application test environment where repeatability is important.

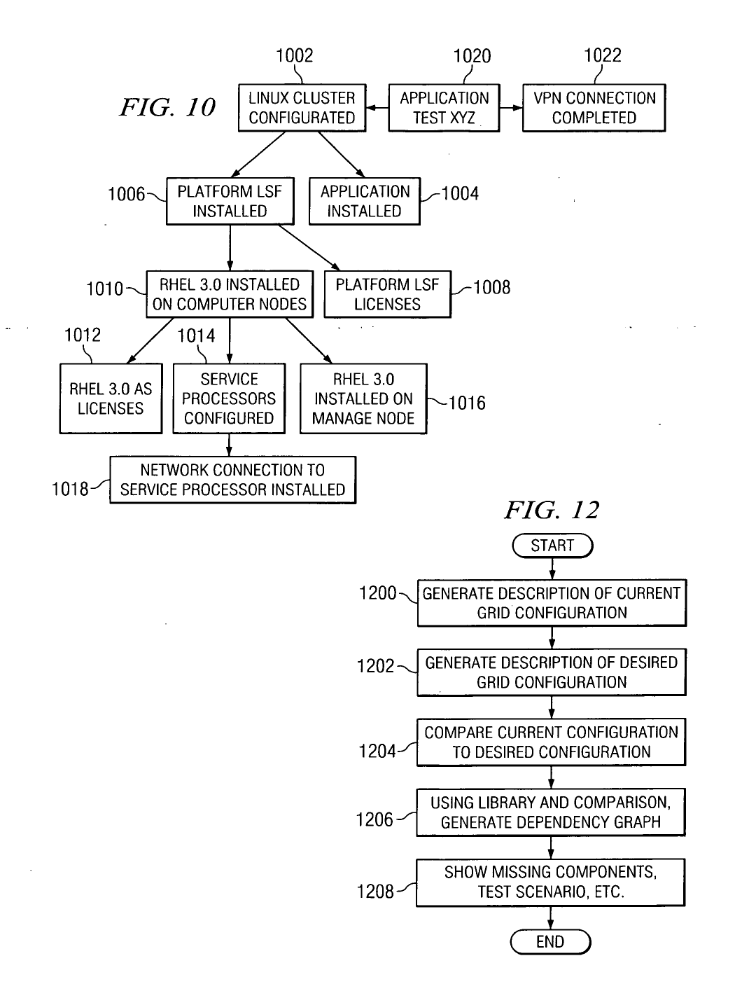

In addition, as shown in block 904, library 900 may be used to generate a list of potential test grid environments based on a description of an application test scenario. In this case, a user describes the application test scenario using workflow language as previously described. The description of the application test scenario is entered as input for a query to library 900. In response, a search engine searches library 900 for similar application test scenarios. Because each application test scenario in library 900 has a corresponding test grid environment, the search engine returns a list of potential test grid environments that may be used with the desired application test scenario. Furthermore, the search engine may return a dependency graph including the test grid environment, application test scenarios, success criteria, and other factors. A user may use the dependency graph to decide how to modify an existing grid environment to a desired grid environment. An example of a dependency graph is shown in FIG. 10. The workflow language may then be used to automatically conform the current grid environment to the desired grid environment.

In addition, as shown in block 906, library 900 may be used to adapt or modify a desired test scenario based on an existing grid environment. In this case, a description of the current grid environment is entered as input for a query to library 900. In response, the search engine returns a list of application test scenarios that are appropriate for use in the current grid environment. Based on information contained in the list, a user may adjust a desired application test scenario, if necessary, such that the application test scenario will function in the existing grid environment. Similarly, if time and resources exist to modify the existing grid environment in some manner, then a range of potential grid environments may be provided as input to a query. In response, the search engine will return a list of application test scenarios that would be appropriate for the list of potential grid environments. The user may then adjust the desired application test scenario accordingly.

FIG. 10 is an example of a dependency graph in accordance with an illustrative embodiment of the present invention. In this example, the dependencies on configuring Linux® Red Hat Enterprise Linux (RHEL) 3.0 cluster 1002 with application 1004 that requires cluster based resource sharing scheduler 1006, Platform LSF. This type of scheduler 1006 is common to many grid application environments. For example, mapping may be performed from other test configurations which require scheduler 1006 to a particular set of dependencies. For example, dependencies to scheduler 1006 are Platform Load Sharing Facility (LSF) licenses 1008 and RHEL 3.0 installed on computer nodes 1010; dependencies to RHEL 3.0 installed on computer nodes 1010 are RHEL 3.0 AS licenses 1012, service processors configured 1014, and RHEL 3.0 installed on manager node 1016; and dependency to service processors configured 1014 is network connection installed to service processor installed 1018. Furthermore, this graph may be used to determine the components of application test XYZ 1020 environment which are predicated on the previous installation or existence of other components such as VPN connection completed 1022.

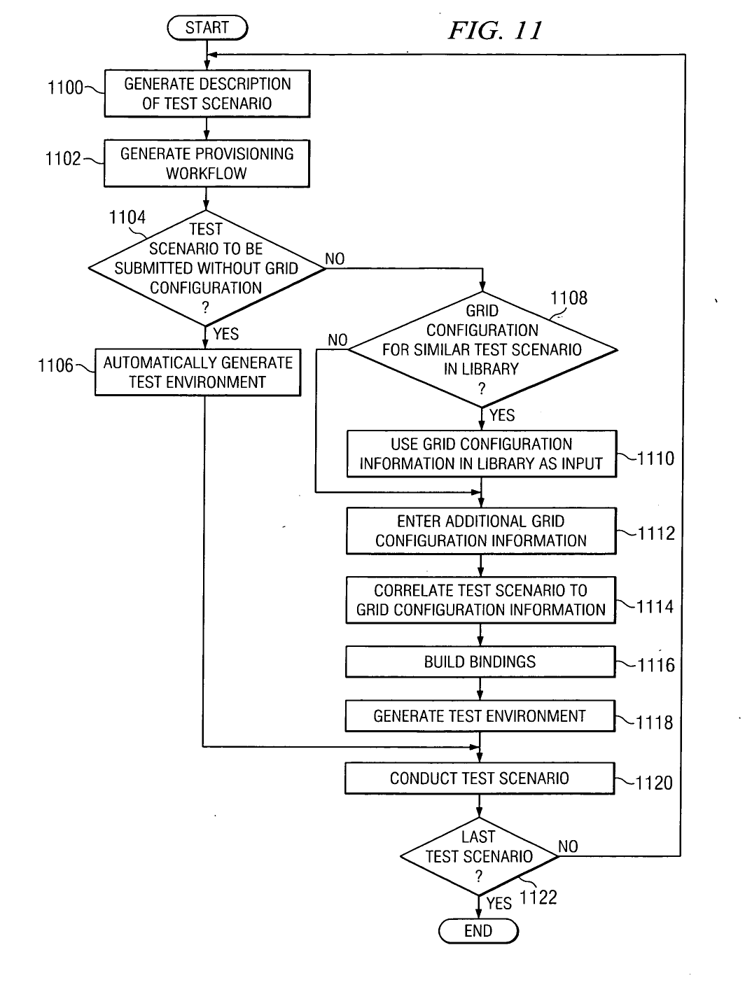

FIG. 11 is a flowchart illustrating a method of generating and conducting one or more test grid environments in a grid computing environment in accordance with an illustrative embodiment of the present invention. This flowchart illustrates that, once a determination that the test will be run in the grid environment, a set of steps occurs to determine if an existing or likewise similar environment already exists on the grid based upon the characteristics of the test submitted. The bindings are generated based upon comparison with the library of test cases, the dependency graphs as well as some interaction with the user as shown in this figure. The method shown in FIG. 11 may be implemented in a grid computing environment as described in relation to FIG. 5 and FIG. 6 using a test snapshot library, such as library 900 in FIG. 9. The method shown in FIG. 11 may be implemented using workflow language as previously described.

Initially, a user or the workflow language program generates a description of a desired test scenario (step 1100). The user or the workflow language program uses workflow language to develop a provisioning workflow (step 1102). The provisioning workflow language, as previously described, is adapted to modify a grid environment to accommodate a particular application test environment.

Next, a determination is made whether the test scenario will be submitted without a particular grid configuration (step 1104). If the test scenario is submitted without a particular grid configuration, then the workflow program automatically generates a test grid environment (step 1106). The workflow program uses an agent installed on the current grid environment to describe the current grid environment. The description of the current grid environment is provided as input to the workflow program. The workflow program then uses the description of the current grid environment, a library, and the desired application test scenario to generate a description of the test grid environment. Alternatively, the agent itself automatically generates a description of the test grid environment by associating key application and test criteria using a library, such as library 900 shown in FIG. 9, and/or by using other factors such as whether the test is performance driven, whether the test is a test of a data query, whether the test application runs on a particular operating system, or other factors. In either case, the agent, user, or workflow program implements the test grid environment by making modifications to the current grid environment. Modifications may include adding a resource, removing a resource, modifying a resource, configuring a resource, changing connections among resources, or otherwise modifying resources on the computing grid. Optionally, the actual test scenario may be conducted on the test grid (step 1120).

Returning to step 1104, if the test scenario is to be submitted with a grid configuration, the workflow program queries a library, such as library 900 in FIG. 9, for whether a particular test grid configuration exists for the test scenario described in step 1100 (step 1108). If a test grid configuration exists in the library for the particular application test scenario, then the workflow program will use the grid configuration information in the library as input when determining the modifications that will be necessary to the current grid environment (step 1110). Subsequently, whether or not such a test grid configuration exists in the library, the user may enter additional current grid environment information as input to the workflow program (step 1112). The workflow program then correlates the particular test scenario with the combined current grid information provided earlier (step 1114). As a result, the workflow program automatically generates a test grid environment that will be suitable for supporting the particular test scenario described in step 1100.

The workflow program then builds any bindings necessary to effectuate changes in the current grid environment (step 1116). For example, configuration scripts to configure the servers, these bindings may be as simple as changing operating system parameters (number of concurrent jobs, to start specific daemons on a UNIX® system) or even more complex bindings such as loading a specific dependant application for the test. Thereafter, the workflow program actually generates the test grid environment (step 1118). Optionally, the workflow program may cause the test scenario to actually be conducted on the test grid environment (step 1120).

Thereafter, the workflow program determines whether additional test scenarios are to be processed (step 1122). If additional test scenarios are to be processed, then the process returns to step 1100 and the process repeats. Otherwise, the process terminates.

FIG. 12 is a flowchart illustrating a method of generating a test scenario in accordance with an illustrative embodiment of the present invention. As with FIG. 11, FIG. 12 demonstrates how a workflow may be generated to compare a requested test to be performed on the grid with existing environment, test templates and dependency graphs, as well as interaction from the requestor. The resultant of this process is a series of bindings in the form of job scripts, user commands, etc. which will be used to build the environment requested. The method shown in FIG. 12 may be implemented in a grid computing environment as described in relation to FIG. 5 and FIG. 6 using a test snapshot library, such as library 900 in FIG. 9. The method shown in FIG. 12 may be implemented using workflow language as previously described.

The process begins as a user or the workflow program generates a description of the current grid configuration (step 1200). Then, the user or the workflow program generates a description of the desired grid configuration (step 1202). The workflow program then compares the current grid configuration to the desired-grid configuration (step 1204). Using the library and the results of the comparison in step 1204, the workflow program generates a dependency graph (step 1206). The dependency graph shows components missing from the current grid configuration that would be used to conduct one or more associated test scenarios (step 1208). An example of a dependency graph is shown in FIG. 10. The process terminates thereafter.

Thus, the present invention provides a method, system, and computer usable code for generating a description of a test environment for use in a grid computing environment. A database containing a number of test snapshots is generated. Each test snapshot reflects a previously used grid test environment, and each test snapshot includes a grid configuration used to implement a particular test scenario for a particular application. When a new test scenario is generated, a description of the new test scenario is entered as a query to the database. Based on the information in the database, a proposed test grid environment description is produced.

The mechanism of the present invention has several advantages over currently available methods for conducting application test scenarios in a grid computing environment. Because the process is semi-automated, a user may design and experiment on test grid environments much more quickly and easily than by using the known manual system of developing and implementing test scenarios. Thus, a provider of grid resources may more quickly adapt to rapidly changing demands of a customer.

The present invention can take the form of an entirely hardware embodiment, an entirely software embodiment or an embodiment containing both hardware and software elements. In an illustrative embodiment, the invention is implemented in software, which includes but is not limited to firmware, resident software, microcode, etc.

Furthermore, the invention can take the form of a computer program product accessible from a computer-usable or computer-readable medium providing program code for use by or in connection with a computer or any instruction execution system. For the purposes of this description, a computer-usable or computer readable medium can be any apparatus that can contain, store, communicate, propagate, or transport the program for use by or in connection with the instruction execution system, apparatus, or device.

The medium can be an electronic, magnetic, optical, electromagnetic, infrared, or semiconductor system (or apparatus or device) or a propagation medium. Examples of a computer-readable medium include a semiconductor or solid state memory, magnetic tape, a removable computer diskette, a random access memory (RAM), a read-only memory (ROM), a rigid magnetic disk and an optical disk. Current examples of optical disks include compact disk-read only memory (CD-ROM), compact disk-read/write (CD-R/W) and DVD.

A data processing system suitable for storing and/or executing program code will include at least one processor coupled directly or indirectly to memory elements through a system bus. The memory elements can include local memory employed during actual execution of the program code, bulk storage, and cache memories which provide temporary storage of at least some program code in order to reduce the number of times code must be retrieved from bulk storage during execution.

Input/output or I/O devices (including but not limited to keyboards, displays, pointing devices, etc.) can be coupled to the system either directly or through intervening I/O controllers.

Network adapters may also be coupled to the system to enable the data processing system to become coupled to other data processing systems or remote printers or storage devices through intervening private or public networks. Modems, cable modem and Ethernet cards are just a few of the currently available types of network adapters.

The description of the present invention has been presented for purposes of illustration and description, and is not intended to be exhaustive or limited to the invention in the form disclosed. Many modifications and variations will be apparent to those of ordinary skill in the art. The embodiment was chosen and described in order to best explain the principles of the invention, the practical application, and to enable others of ordinary skill in the art to understand the invention for various embodiments with various modifications as are suited to the particular use contemplated.

What is claimed is:

1. A method in a data processing system for generating a description of a test grid environment for use in a grid computing environment, said method comprising:
querying a database with a query, wherein the database comprises a plurality of test snapshots and wherein the query includes a test scenario description as an input; and
generating a test grid environment description based on results of the query.

2. The method of claim 1, wherein each test snapshot in the plurality of test snapshots comprises an association of a description of a particular grid configuration with a particular test scenario.

3. The method of claim 1, further comprising:
describing a current grid configuration of a computing grid to produce a current grid configuration description;
comparing the current grid configuration description with the test grid environment description to produce a comparison; and
generating a dependency graph based on the comparison.

4. The method of claim 3, wherein the dependency graph comprises a description of how resources in the current grid should be modified in order to effect a change from the current grid configuration to the test grid environment.

5. The method of claim 1, further comprising:
describing a current grid configuration of a computing grid to produce a current grid configuration description; and
changing the current grid configuration to match the test grid environment description, wherein the test grid environment is produced.

6. The method of claim 5, further comprising:
performing a test scenario in the test grid environment.

7. The method of claim 3, further comprising:
changing the current grid configuration based on the dependency graph to produce the test grid environment.

8. The method of claim 7, further comprising:
performing a test scenario in the test grid environment.

9. A data processing system comprising:
a bus system;
a communications system connected to the bus system;
a memory connected to the bus system, wherein the memory includes a set of instructions;
an instruction execution unit; and
a processing unit connected to the bus system, wherein the processing unit executes the set of instructions to query a database with a query, wherein the database comprises a plurality of test snapshots and wherein the query includes a test scenario description as an input; and generate a test grid environment description based on results of the query.

10. The data processing system of claim 9, wherein each test snapshot in the plurality of test snapshots comprises an association of a description of a particular grid configuration with a particular test scenario.

11. The data processing system of claim 9, further comprising:
a set of instructions to describe a current grid configuration of a computing grid to produce a current grid configuration description; compare the current grid configuration description with the test grid environment description to produce a comparison; and generate a dependency graph based on the comparison.

12. The data processing system of claim 11, wherein the dependency graph comprises a description of how resources in the current grid should be modified in order to effect a change from the current grid configuration to the test grid environment.

13. The data processing system of claim 9, further comprising:
a set of instructions to describe a current grid configuration of a computing grid to produce a current grid configuration description; and change the current grid configuration to match the test grid environment description, wherein the test grid environment is produced.

14. The data processing system of claim 13, further comprising:
a set of instructions to perform a test scenario in the test grid environment.

15. The data processing system of claim 11, further comprising:
a set of instructions to change the current grid configuration based on the dependency graph to produce the test grid environment.

16. The data processing system of claim 15, further comprising:
a set of instructions to perform a test scenario in the test grid environment.

17. A computer program product comprising:
a computer usable medium including computer usable program code for generating a description of a test grid environment for use in a grid computing environment, the computer program product including;
computer usable program code for querying a database with a query, wherein the database comprises a plurality of test snapshots and wherein the query includes a test scenario description as an input; and
computer usable program code for generating a test grid environment description based on results of the query.

18. The computer program product of claim 17, wherein each test snapshot in the plurality of test snapshots comprises an association of a description of a particular grid configuration with a particular test scenario.

19. The computer program product of claim 17, further comprising:
computer usable program code for describing a current grid configuration of a computing grid to produce a current grid configuration description;
computer usable program code for comparing the current grid configuration description with the test grid environment description to produce a comparison; and
computer usable program code for generating a dependency graph based on the comparison.

20. The computer program product of claim 19, wherein the dependency graph comprises a description of how resources in the current grid should be modified in order to effect a change from the current grid configuration to the test grid environment.

21. The computer program product of claim 17, further comprising:
computer usable program code for describing a current grid configuration of a computing grid to produce a current grid configuration description; and
computer usable program code for changing the current grid configuration to match the test grid environment description, wherein the test grid environment is produced.

22. The computer program product of claim 21, further comprising:
computer usable program code for performing a test scenario in the test grid environment.

23. The computer program product of claim 19, further comprising:
computer usable program code for changing the current grid configuration based on the dependency graph to produce the test grid environment.

24. The computer program product of claim 23, further comprising:
computer usable program code for performing a test scenario in the test grid environment.
